(19) United States
(12) Patent Application Publication
(10) Pub. No.: US 2020/0105461 A1
(43) Pub. Date: Apr. 2, 2020

(54) TRANSFORMER

(71) Applicant: DELTA ELECTRONICS, INC., Taoyuan City (TW)

(72) Inventors: Ssu-Wei Fu, Taoyuan City (TW); Hsin-Wei Tsai, Taoyuan City (TW); Zengyi Lu, Taoyuan City (TW)

(21) Appl. No.: 16/227,218

(22) Filed: Dec. 20, 2018

(30) Foreign Application Priority Data
Sep. 28, 2018 (CN) 201811141833.4

(51) Int. Cl. H01F 27/28; H01F 27/24; H01F 27/29; H01F 27/30; H01F 27/32; H05K 1/18

(52) U.S. Cl. CPC H01F 27/2852; H01F 27/24; H01F 27/29; H01F 2027/065; H01F 27/325; H01F 27/2866; H05K 1/18; H01F 27/306

(57) ABSTRACT

The present disclosure discloses a transformer. The transformer includes a magnetic core, at least one winding assembly and at least one conductive plate assembly. The magnetic core includes a magnetic core pillar. The at least one winding assembly is disposed around the magnetic core pillar to receive an input power. The at least one conductive plate assembly is disposed around the magnetic core pillar and electromagnetic coupled with the winding assembly via the magnetic core. The conductive plate assembly includes at least two conductive plates. Each of the conductive plates includes a main body and a pin extending outwardly from the corresponding main body. The extension directions of the pins of the at least two conductive plates extending outwardly from the corresponding main bodies are different from each other. The pins are connected to different circuit boards. Each of the circuit boards includes at least one rectifier.

### TECHNICAL FIELD

The present disclosure relates to a transformer, and more particularly to a transformer including plural pins extending outwardly from respective main bodies at different directions.

### BACKGROUND OF THE DISCLOSURE

Nowadays, transformer has been widely applied to a variety of electronic devices or equipment for adjusting voltage based on the theory of electromagnetic induction conversion, so that the voltage with a desired range is provided for powering the electronic devices or equipment. With increasing development of science and technology, the general trends in designing electronic devices are toward minimization, high integration and high power. The structure design and the practical demand of the transformer are more difficult. Therefore, it is important to develop a transformer with miniaturized size and high power density.

Generally, the transformer includes a magnetic core, a winding assembly and a conductive plate assembly. The winding assembly and the conductive plate assembly surround portion of the magnetic core, respectively. The conductive plate assembly includes plural conductive plates. Each one of the conductive plates includes a main body and a pin. The pin is extending outwardly from the corresponding main body for allowing the transformer to convey the current therethrough. However, the pins of the conductive plates of the transformer are extending outwardly from respective main bodies at the same direction. After the plural conductive plates are stacked sequentially, the pins of the conductive plates are arranged in the same side of the transformer. In other words, the pins are extending outwardly from the same side of the magnetic core. Under this circumstance, the available space of the transformer is limited by the positions of the pins. The transformer can't be miniaturized, and the power density of the transformer is lower. Moreover, the transformer conveys the current via the pins in the same direction, so that the transformer fails to perform current distribution. Consequently, the efficiency of the transformer is reduced.

Therefore, there is a need of providing a transformer in order to address the above issues.

### SUMMARY OF THE DISCLOSURE

An object of an embodiment of the present disclosure is to provide a transformer in order to address the issues that the prior art has larger size, lower power density and reduced efficiency.

Another object of an embodiment of the present disclosure is to provide a transformer having miniaturized size, enhanced power density, and enhanced efficiency.

In accordance with an aspect of the present disclosure, a transformer is provided. The transformer includes a magnetic core, at least one winding assembly and at least one conductive plate assembly. The magnetic core includes a magnetic core pillar. The at least one winding assembly is disposed around the magnetic core pillar to receive an input power. The at least one conductive plate assembly is disposed around the magnetic core pillar and electromagnetic coupled with the winding assembly via the magnetic core. The conductive plate assembly includes at least two conductive plates. Each of the conductive plates includes a main body and a pin extending outwardly from the corresponding main body. The extension directions of the pins of the at least two conductive plates extending outwardly from the corresponding main bodies are different from each other. The pins of the at least two conductive plates are connected to different circuit boards. Each of the circuit boards includes at least one rectifier.

In accordance with another aspect of the present disclosure, a transformer is provided. The transformer includes a magnetic core, a bobbin, at least one winding assembly and at least one conductive plate assembly. The magnetic core includes a magnetic core pillar. The bobbin is disposed around the magnetic core pillar. The at least one winding assembly is disposed around the bobbin to receive an input power. The at least one conductive plate assembly is disposed around the bobbin and electromagnetic coupled with the winding assembly via the magnetic core. The conductive plate assembly includes at least two conductive plates. Each of the conductive plates includes a main body and a pin extending outwardly from the corresponding main body. The extension directions of the pins of the at least two conductive plates extending outwardly from the corresponding main bodies are different from each other. The pins of the at least two conductive plates are connected to different circuit boards. Each of the circuit boards includes at least one rectifier.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a transformer according to a first embodiment of the present disclosure;

FIG. 2 is a schematic perspective view illustrating the transformer of FIG. 1 connected to circuit boards, wherein part of a magnetic core of the transformer is omitted;

FIG. 3 is a schematic perspective view illustrating the transformer of FIG. 1 connected to circuit boards, wherein a magnetic core of the transformer is completely shown;

FIG. 4 is a schematic block diagram illustrating a transformer of FIG. 1 applied to a power conversion circuit;

FIG. 5 is a schematic perspective view illustrating a transformer according to a second embodiment of the present disclosure;

FIG. 6 is a schematic perspective view illustrating a transformer according to a third embodiment of the present disclosure;

FIG. 7 is a schematic perspective view illustrating a transformer according to a fourth embodiment of the present disclosure;

FIG. 8 is a schematic exploded view illustrating the transformer of FIG. 7; and

FIG. 9 is a schematic perspective view illustrating a winding assembly of the transformer of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

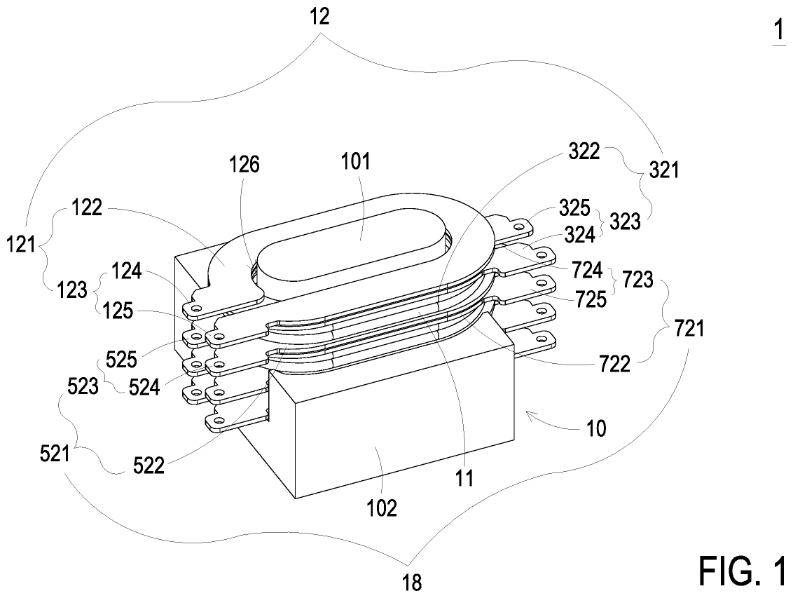

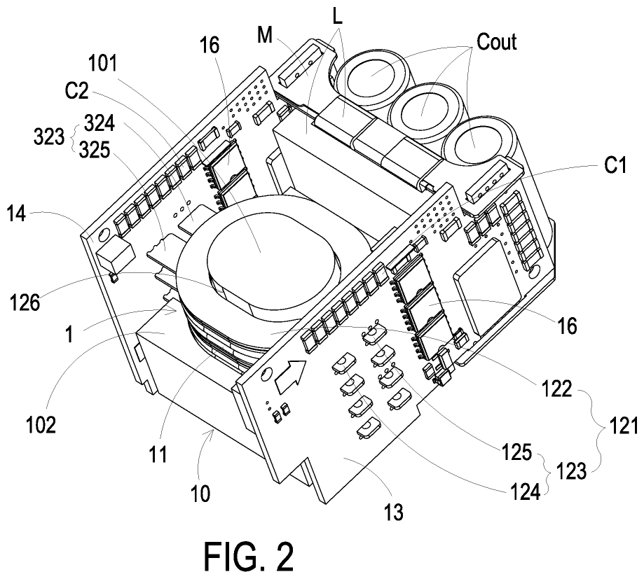

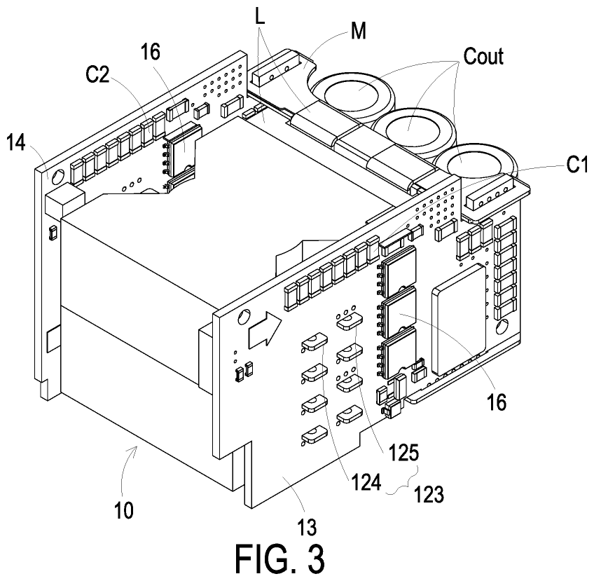

FIG. 1 is a schematic perspective view illustrating a transformer according to a first embodiment of the present disclosure, FIG. 2 is a schematic perspective view illustrating the transformer of FIG. 1 connected to circuit boards, wherein part of a magnetic core of the transformer is omitted, and FIG. 3 is a schematic perspective view illustrating the transformer of FIG. 1 connected to circuit boards, wherein a magnetic core of the transformer is completely shown. As shown in FIGS. 1, 2 and 3, the transformer 1 of this embodiment includes a magnetic core 10, at least one winding assembly 11 and at least one conductive plate assembly. The magnetic core 10 includes a first magnetic part and a second magnetic part, as shown in FIG. 3. The magnetic core 10 is but not limited to an EE shaped magnetic core. The magnetic core 10 includes a magnetic core pillar 101 disposed at the center position of the magnetic core 10, and two lateral pillars 102 disposed at the two opposite sides of the magnetic core pillar 101. To simplify the description of the present disclosure, one E shaped magnet part of the magnetic core 10 is omitted in FIG. 2. The at least one winding assembly 11 is disposed on the magnetic core pillar 101 and disposed around the magnetic core pillar 101. The at least one conductive plate assembly is disposed on the magnetic core pillar 101 and disposed around the magnetic core pillar 101. In this embodiment, the at least one conductive plate assembly includes but not limited to a first conductive plate assembly 12 and a second conductive plate assembly 18. The first conductive plate assembly 12 and the second conductive plate assembly 18 are disposed around the magnetic core pillar 101, respectively. The first conductive plate assembly 12 is electromagnetic coupled with the corresponding winding assembly 11 via the magnetic core 10. The second conductive plate assembly 18 is electromagnetic coupled with the corresponding winding assembly 11 via the magnetic core 10. In this embodiment, the winding assembly 11 is disposed between the first conductive plate assembly 12 and the second conductive plate assembly 18.

In this embodiment, the first conductive plate assembly 12 includes at least two conductive plates, such as a first conductive plate 121 and a second conductive plate 321. Preferably but not exclusively, the first conductive plate 121 and the second conductive plate 321 are copper plates or printed circuit boards. In this embodiment, the first conductive plate 121 and the second conductive plate 321 are copper plates. In other embodiment, the first conductive plate 121 and the second conductive plate 321 are printed circuit boards, the first conductive plate 121 and the first circuit board 13 are integrated formed into one piece, and the second conductive plate 321 and the second circuit board 14 are integrated formed into one piece.

The first conductive plate 121 includes a main body 122 and a pin 123 extending outwardly from the main body 122. The second conductive plate 321 includes a main body 322 and a pin 323 extending outwardly from the main body 322. The extension direction of the pin 123 of the first conductive plate 121 extending outwardly from the main body 122 is different from the extension direction of the pin 323 of the second conductive plate 321 extending outwardly from the main body 322. In other words, the pin 123 of the first conductive plate 121 and the pin 323 of the second conductive plate 321 are extending outwardly from the two opposite sides of the magnetic core 10, respectively. The pin 123 of the first conductive plate 121 is vertically connected to the first circuit board 13. The pin 323 of the second conductive plate 321 is vertically connected to the second circuit board 14. The first circuit board 13 includes a rectifier 16 and a first capacitor C1 corresponding to the pin 123 of the first conductive plate 121. The second circuit board 14 includes a rectifier 16 and a second capacitor C2 corresponding to the pin 323 of the second conductive plate 321. An inductor L and an output capacitor Cout are disposed between the first circuit board 13 and the second circuit board 14. The inductor L and the output capacitor Cout are respectively connected to the first circuit board 13 and the second circuit board 14 via an interconnection board M.

In this embodiment, the second conductive plate assembly 18 includes at least two conductive plates, such as a first conductive plate 521 and a second conductive plate 721. Preferably but not exclusively, the first conductive plate 521 and the second conductive plate 721 are copper plates or printed circuit boards, respectively. The first conductive plate 521 includes a main body 522 and a pin 523 extending outwardly from the main body 522. The second conductive plate 721 includes a main body 722 and a pin 723 extending outwardly from the main body 722. The extension direction of the pin 523 of the first conductive plate 521 extending outwardly from the main body 522 is different from the extension direction of the pin 723 of the second conductive plate 721 extending outwardly from the main body 722. In other words, the pin 523 of the first conductive plate 521 and the pin 723 of the second conductive plate 721 are extending outwardly from the two opposite sides of the magnetic core 10, respectively. The pin 523 of the first conductive plate 521 is vertically connected to the first circuit board 13. The pin 723 of the second conductive plate 721 is vertically connected to the second circuit board 14. The first circuit board 13 includes a rectifier 16 corresponding to the pin 523 of the first conductive plate 521. The second circuit board 14 includes a rectifier 16 corresponding to the pin 723 of the second conductive plate 721.

In some embodiments, the extension direction of the pin 123 of the first conductive plate 121 of the first conductive plate assembly 12 extending outwardly from the main body 122 is the same with the extension direction of the pin 523 of the first conductive plate 521 of the second conductive plate assembly 18 extending outwardly from the main body 522. In other words, the pin 123 of the first conductive plate 121 and the pin 523 of the first conductive plate 521 are extending outwardly from the same side of the magnetic core 10, respectively. The extension direction of the pin 323 of the second conductive plate 321 of the first conductive plate assembly 12 extending outwardly from the main body 322 is the same with the extension direction of the pin 723 of the second conductive plate 721 of the second conductive plate assembly 18 extending outwardly from the main body 722. In other words, the pin 323 of the second conductive plate 321 and the pin 723 of the second conductive plate 721 are extending outwardly from the same side of the magnetic core 10, respectively. In this embodiment, the first conductive plate 121 of the first conductive plate assembly 12, the second conductive plate 321 of the first conductive plate assembly 12, the first conductive plate 521 of the second conductive plate assembly 18 and the second conductive plate 721 of the second conductive plate assembly 18 are stacked sequentially and disposed around the magnetic core pillar 101 of the magnetic core 10, respectively.

In this embodiment, the first conductive plate 121 of the first conductive plate assembly 12 includes a hole 126 disposed at the center of the main body 122 of the first conductive plate 121. Similarly, the second conductive plate 321 includes a hole (not shown) disposed at the center of the main body 322 of the second conductive plate 321. The hole 126 of the first conductive plate 121 of the first conductive plate assembly 12 is corresponding in position to the hole of the second conductive plate 321 of the first conductive plate assembly 12 so as to form an insertion part of the first conductive plate assembly 12. The insertion part of the first conductive plate assembly 12 allows the magnetic core pillar 101 of the magnetic core 10 to insert therein, so that the first conductive plate assembly 12 is disposed around the magnetic core pillar 101 through the insertion part of the first conductive plate assembly 12.

The first conductive plate 521 of the second conductive plate assembly 18 includes a hole (not shown) disposed at the center of the main body 522 of the first conductive plate 521. Similarly, the second conductive plate 721 includes a hole (not shown) disposed at the center of the main body 722 of the second conductive plate 721. The hole of the first conductive plate 521 of the second conductive plate assembly 18 is corresponding in position to the hole of the second conductive plate 721 of the second conductive plate assembly 18 so as to form an insertion part of the second conductive plate assembly 18. The insertion part of the second conductive plate assembly 18 allows the magnetic core pillar 101 of the magnetic core 10 to insert therein, so that the second conductive plate assembly 18 is disposed around the magnetic core pillar 101 through the insertion part of the second conductive plate assembly 18. In addition, the insertion part of the first conductive plate assembly 12 is corresponding in position to the insertion part of the second conductive plate assembly 18.

Moreover, as shown in FIGS. 1, 2 and 3, the magnetic core 10 of the transformer 1 of this embodiment is the EE shaped magnetic core. The magnetic core pillar 101 of the magnetic core 10 is formed by the middle pillars of the EE shaped magnetic core. The two lateral pillars 102 of the magnetic core 10 are disposed at the two opposite sides of the middle pillars of the EE shaped magnetic core. The winding assembly 11, the first conductive plate assembly 12 and the second conductive plate assembly 18 are disposed between the magnetic core pillar 101 and the two lateral pillars 102 and are disposed around the magnetic core pillar 101. In this embodiment, the first conductive plate 121 of the first conductive plate assembly 12 is disposed adjacent to the second conductive plate 321 of the first conductive plate assembly 12. An insulation plate is disposed between the first conductive plate 121 and the second conductive plate 321 of the first conductive plate assembly 12. The first conductive plate 521 of the second conductive plate assembly 18 is disposed adjacent to the second conductive plate 721 of the second conductive plate assembly 18. An insulation plate is disposed between the first conductive plate 521 and the second conductive plate 721 of the second conductive plate assembly 18. The at least one winding assembly 11 is disposed around the magnetic core pillar 101 of the magnetic core 10 and disposed between the second conductive plate 321 of the first conductive plate assembly 12 and the first conductive plate 521 of the second conductive plate assembly 18. In some embodiments, the transformer 1 includes plural winding assemblies 11 and plural conductive plate assemblies 12, 18. The plural winding assemblies 11 and the plural conductive plate assemblies 12, 18 are arranged interlaced.

In some embodiments, the width of the main body 122 of the first conductive plate 121 of the first conductive plate assembly 12 is larger than two times of the thickness of the first conductive plate 121 of the first conductive plate assembly 12. The width of the main body 322 of the second conductive plate 321 of the first conductive plate assembly 12 is larger than two times of the thickness of the second conductive plate 321 of the first conductive plate assembly 12. The width of the main body 522 of the first conductive plate 521 of the second conductive plate assembly 18 is larger than two times of the thickness of the first conductive plate 521 of the second conductive plate assembly 18. The width of the main body 722 of the second conductive plate 721 of the second conductive plate assembly 18 is larger than two times of the thickness of the second conductive plate 721 of the second conductive plate assembly 18. For example, the width of the main body 122 of the first conductive plate 121 of the first conductive plate assembly 12 is 3 mm, and the thickness of the first conductive plate 121 of the first conductive plate assembly 12 is 1 mm. The width of the main body 122 of the first conductive plate 121 of the first conductive plate assembly 12 is 2.5 mm, and the thickness of the first conductive plate 121 of the first conductive plate assembly 12 is 0.5 mm. The width and the thickness of the conductive plate are not limited to the above embodiment and can be varied according to the practical requirements.

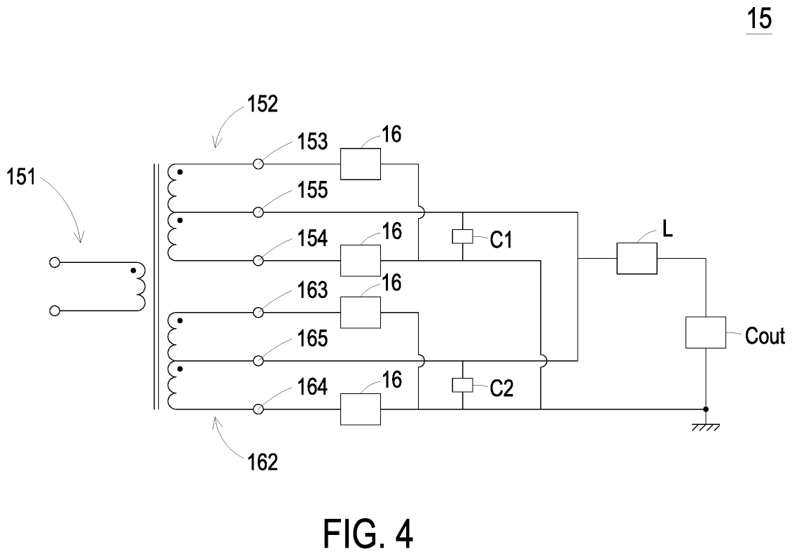

FIG. 4 is a schematic block diagram illustrating a transformer of FIG. 1 applied to a power conversion circuit. As shown in FIGS. 1 to 4, the transformer 1 is applied to a power conversion circuit 15. The power conversion circuit 15 includes a primary winding 151, a first secondary winding 152 and a second secondary winding 162. The winding assembly 11 of the transformer 1 forms the primary winding 151 of the power conversion circuit 15. The first secondary winding 152 is a center tap and includes a first end 153, a second end 154 and a first center tap end 155. The first end 153 and the second end 154 are connected to the corresponding rectifiers 16, respectively. The first center tap 155 is connected to the first capacitor C1 and one end of the inductor L. The other end of the inductor L is connected to the output capacitor Cout. The second secondary winding 162 is a center tap and includes a third end 163, a fourth end 164 and a second center tap end 165. The third end 163 and the fourth end 164 are connected to the corresponding rectifiers 16, respectively. The second center tap end 165 is connected to the second capacitor C2 and one end of the inductor L. The first conductive plate assembly 12 and the second conductive plate assembly 18 of the transformer 1 form the first secondary winding 152 and the second secondary winding 162 of the power conversion circuit 15, respectively. The pin 123 of the first conductive plate 121 of the first conductive plate assembly 12 includes a first leg 124 and a second leg 125. The pin 323 of the second conductive plate 321 of the first conductive plate assembly 12 includes a first leg 324 and a second leg 325. The pin 523 of the first conductive plate 521 of the second conductive plate assembly 18 includes a first leg 524 and a second leg 525. The pin 723 of the second conductive plate 721 of the second conductive plate assembly 18 includes a first leg 724 and a second leg 725.

In this embodiment, the first leg 124 of the first conductive plate 121 of the first conductive plate assembly 12 is connected to the first center tap 155. The second leg 125 of the first conductive plate 121 of the first conductive plate assembly 12 is connected to the first end 153. The first leg 524 of the first conductive plate 521 of the second conductive plate assembly 18 is connected to the first center tap 155. The second leg 525 of the first conductive plate 521 of the second conductive plate assembly 18 is connected to the second end 154. The first leg 324 of the second conductive plate 321 of the first conductive plate assembly 12 is connected to the second center tap 165. The second leg 325 of the second conductive plate 321 of the first conductive plate assembly 12 is connected to the third end 163. The first leg 724 of the second conductive plate 721 of the second conductive plate assembly 18 is connected to the second center tap 165. The second leg 725 of the second conductive plate 721 of the second conductive plate assembly 18 is connected to the fourth end 164.

Moreover, the first end 153 and the second end 154 of the first secondary winding 152 and the third end 163 and the fourth end 164 of the second secondary winding 162 are connected to the corresponding rectifiers 16, respectively. According to the present disclosure, the extension directions of the first leg 124 and the second leg 125 of the first conductive plate 121 of the first conductive plate assembly 12 are the same with the extension directions of the first leg 524 and the second leg 525 of the first conductive plate 521 of the second conductive plate assembly 18. Therefore, the first leg 124 and the second leg 125 of the first conductive plate 121 and the first leg 524 and the second leg 525 of the first conductive plate 521 are connected to the first circuit board 13. Moreover, the extension directions of the first leg 324 and the second leg 325 of the second conductive plate 321 of the first conductive plate assembly 12 are the same with the extension directions of the first leg 724 and the second leg 725 of the second conductive plate 721 of the second conductive plate assembly 18. Therefore, the first leg 324 and the second leg 325 of the second conductive plate 321 and the first leg 724 and the second leg 725 are connected to the second circuit board 14. Comparing with the conventional transformer, the transformer 1 of the present disclosure has small size and higher power density and makes an intensive utilization of space. Moreover, the transformer 1 of this embodiment conveys the current to the rectifiers via the pins having different extension directions. That is, the transformer 1 divides and conveys current to the rectifiers, so that the efficiency of the transformer 1 is higher.

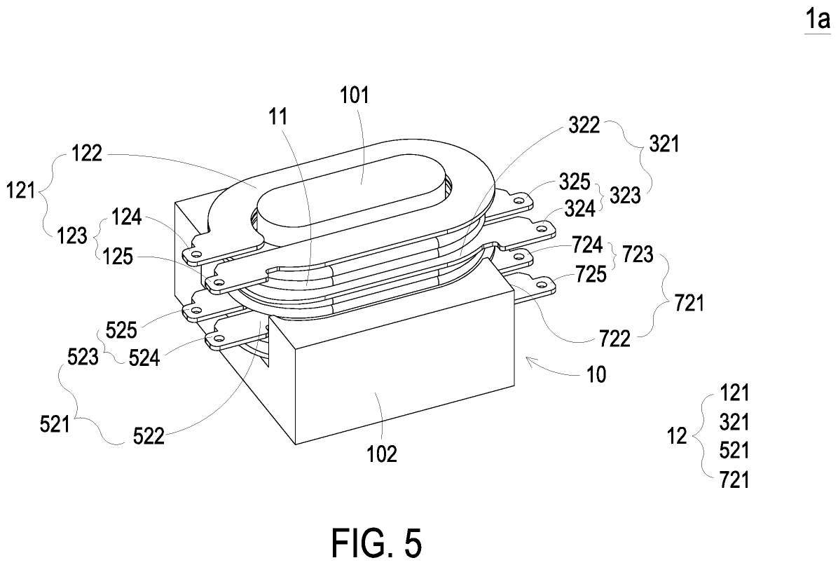

FIG. 5 is a schematic perspective view illustrating a transformer according to a second embodiment of the present disclosure. As shown in FIG. 5, the structures and operations of the transformer 1a of this embodiment are similar to that of the transformer 1 of FIG. 1, wherein component parts and elements corresponding to those of the first embodiment are designated by identical numeral references, and detailed descriptions thereof are omitted. Comparing with the transformer 1 of FIG. 1, the conductive plate assembly of the transformer 1a of this embodiment only includes a single conductive plate assembly 12. The conductive plate assembly 12 includes two first conductive plates 121, 521 and two second conductive plates 321, 721. Moreover, the winding assembly 11 of the transformer 1 of FIG. 1 is disposed between the first conductive plate assembly 12 and the second conductive plate assembly 18. Comparing with the transformer 1 of FIG. 1, the winding assembly 11 of the transformer 1a of this embodiment is disposed between the first conductive plate 121 and the second conductive plate 321, disposed between the second conductive plate 321 and the first conductive plate 521, and disposed between the first conductive plate 521 and the second conductive plate 721.

Please refer to FIGS. 4 and 5, the two first conductive plates 121, 521 of the conductive plate assembly 12 form the first secondary winding assembly 152. The two second conductive plate 321, 721 form the second secondary winding assembly 162. The pin 123 of the first conductive plate 121 includes a first leg 124 and a second leg 125. The pin 523 of the first conductive plate 521 includes a first leg 524 and a second leg 525. The pin 323 of the second conductive plate 321 includes a first leg 324 and a second leg 325. The pin 723 of the second conductive plate 721 includes a first leg 724 and a second leg 725.

The first leg 124 of the first conductive plate 121 is connected to the first center tap end 155. The second leg 125 of the first conductive plate 121 is connected to the first end 153. The first leg 524 of the first conductive plate 521 is connected to the first center tap 155. The second leg 525 of the first conductive plate 521 is connected to the second end 154. The first leg 324 of the second conductive plate 321 is connected to the second center tap end 165. The second leg 325 of the second conductive plate 321 is connected to the third end 163. The first leg 724 of the second conductive plate 721 is connected to the second center tap end 165. The second leg 725 of the second conductive plate 721 is connected to the fourth end 164.

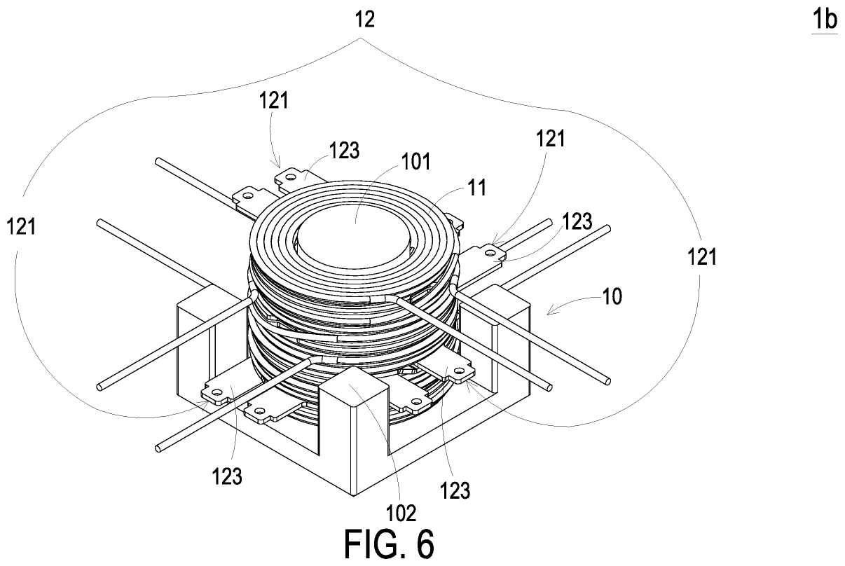

FIG. 6 is a schematic perspective view illustrating a transformer according to a third embodiment of the present disclosure. As shown in FIG. 6, the structures and operations of the transformer 1b of this embodiment are similar to that of the transformer 1 of FIG. 1, wherein component parts and elements corresponding to those of the first embodiment are designated by identical numeral references, and detailed descriptions thereof are omitted. Comparing with the transformer 1 of FIG. 1, the magnetic core 10 of the transformer 1b of this embodiment includes a magnetic core pillar 101 and four lateral pillars 102 disposed around the magnetic core pillar 101. The magnetic core pillar 101 is disposed at the center position of the magnetic core 10. There is a gap between one of the lateral pillars 102 and the other adjacent lateral pillar 102, i.e., the four lateral pillars 102 are separated from each other by a distance. In addition, the conductive plate assembly 12 of the transformer 1b of this embodiment includes four conductive plates 121. The extension directions of the pins 123 of the conductive plates 121 extending outwardly from the respective main bodies (not shown) are different from each other. For example, one pin of the four conductive plates 121 extending outwardly from the main body (not shown) is defined as 0 degree. The rest pins of the conductive plates 121 extending outwardly form the respective main bodies are 90 degree, 180 degree and 270 degree sequentially. In detail, the pins 123 of the four conductive plates 121 are extending outwardly from four different sides of the magnetic core 10, respectively. The extension directions of the pins 123 of the conductive plates 121 extending outwardly from the respective main bodies are not limited to the above embodiment and can be varied according to the practical requirement.

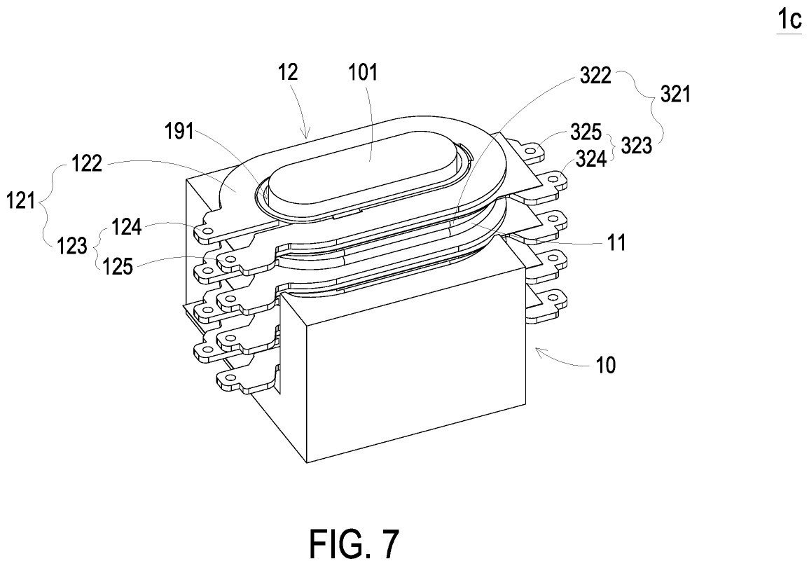

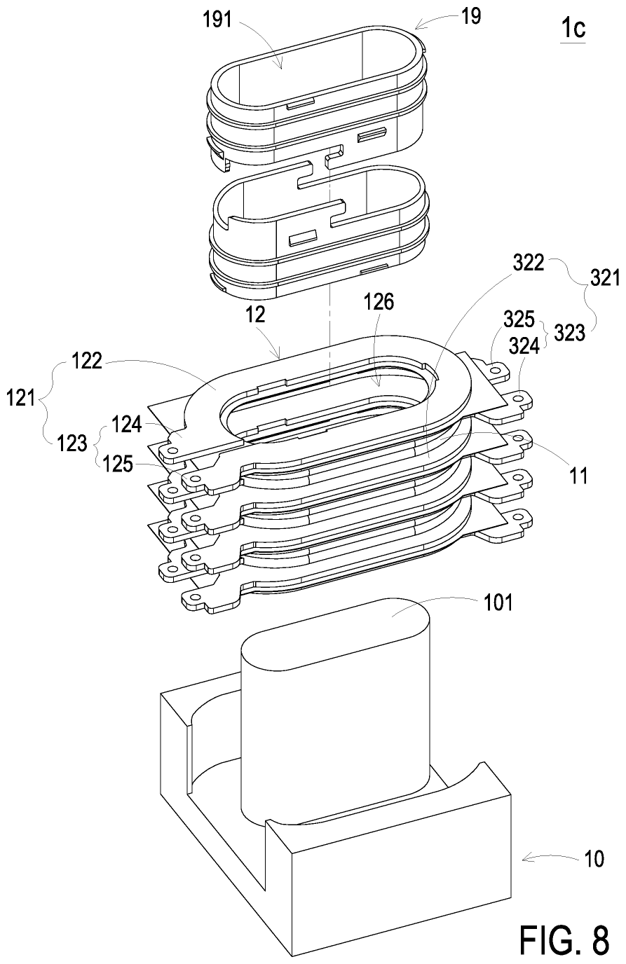

FIG. 7 is a schematic perspective view illustrating a transformer according to a fourth embodiment of the present disclosure. FIG. 8 is a schematic exploded view illustrating the transformer of FIG. 7. As shown in FIGS. 7 and 8, the structures and operations of the transformer 1c of this embodiment are similar to that of the transformer 1 of FIG. 1, wherein component parts and elements corresponding to those of the first embodiment are designated by identical numeral references, and detailed descriptions thereof are omitted. Comparing with the transformer 1 of FIG. 1, the transformer 1c includes a bobbin 19. The bobbin 19 includes a channel 191 for allowing the magnetic core pillar 101 of the magnetic core 10 to insert therein. The bobbin 19 is disposed around the magnetic core pillar 101 of the magnetic core 10. The main body 122 of the first conductive plate 121 includes the corresponding hole 126. The main body 322 of the second conductive plate 321 also includes a corresponding hole. The hole 126 of the main body 122 of the first conductive plate 121 is corresponding in position to the hole of the main body 322 of the second conductive plate 321 so as to form an insertion part of the first conductive plate assembly 12. The insertion part of the first conductive plate assembly 12 allows the bobbin 19 to insert therein.

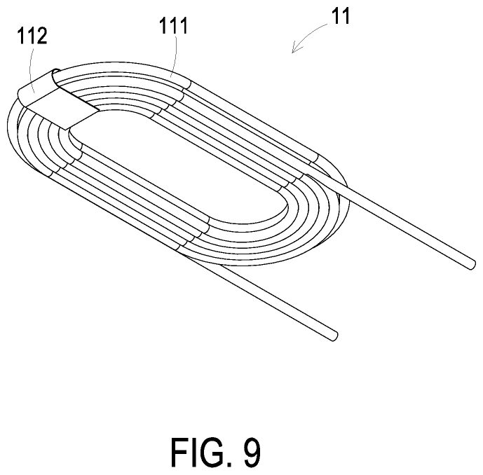

FIG. 9 is a schematic perspective view illustrating the winding assembly of the transformer of the present disclosure. As shown in FIG. 9, the winding assembly 11 includes a wire 111 and a fixing element 112. The wire 111 of the winding assembly 11 is fixed by the fixing element 112 of the winding assembly 11. In an embodiment, the fixing element 112 is tape or gumming. After the wire 111 is completely rolled, the wire 111 is fixed by the tape or gumming. In some embodiments, the fixing element 112 is adhesive glue or adhesive bond covered on the outer layer of the wire 111, i.e., the wire 111 is self-adhesive wire. Therefore, by heating or other way, the adhesive glue or the adhesive bond has adhesive effect or fixing effect to fix the wire 111.

From the above descriptions, the present disclosure provides a transformer. The transformer includes at least one conductive plate assembly. The conductive plate assembly includes at least two conductive plates. The pins of the at least two conductive plates extending outwardly from the corresponding main bodies are different from each other. Comparing with the traditional transformer, the transformer of the present disclosure uses the space which the traditional transformer can't use to connect with the corresponding rectifiers. For example, the pins which located at the two opposite sides or the four different sides of the magnetic core of the transformer of the present disclosure are connected to the corresponding rectifiers, respectively. Therefore, the transformer of the present disclosure uses the pins extending at different directions to connect with the corresponding rectifiers to convey the current. That is to say, transformer of the present disclosure divides and conveys current to the rectifiers, so that the size of the present disclosure is smaller, the efficiency is higher, and the power density is higher.

While the disclosure has been described in terms of what is presently considered to be the most practical and preferred embodiments, it is to be understood that the disclosure needs not be limited to the disclosed embodiment.

What is claimed is:

1. A transformer, comprising:
a magnetic core comprising a magnetic core pillar;
at least one winding assembly disposed around the magnetic core pillar for receiving an input power; and
at least one conductive plate assembly disposed around the magnetic core pillar and electromagnetic coupled with the winding assembly via the magnetic core;
wherein the conductive plate assembly comprises at least two conductive plates, each of the conductive plates comprises a main body and a pin extending outwardly from the corresponding main body, wherein the extension directions of the pins of the at least two conductive plates extending outwardly from the corresponding main bodies are different from each other, the pins of the at least two conductive plates are connected to different circuit boards, and each of the circuit boards comprises at least one rectifier.

2. The transformer according to claim 1, wherein the main body of each one of the conductive plates has a hole, the holes of the at least two conductive plates of each one of the conductive plate assembly are corresponding in position to each other so as to form an insertion part of the conductive plate assembly for allowing the magnetic core pillar to insert therein, wherein the conductive plate assembly is disposed around the magnetic core pillar.

3. The transformer according to claim 1, wherein the magnetic core is an EE shaped magnetic core, the magnetic core pillar is formed by two middle pillars of the EE shaped magnetic core, and the pins of the at least two conductive plates extending outwardly form the corresponding main bodies are opposite to each other.

4. The transformer according to claim 1, wherein each one of the conductive plates is a copper plate or a printed circuit board.

5. The transformer according to claim 1, wherein the transformer comprises plural winding assemblies and plural conductive plate assemblies, and the plural winding assemblies and the plural conductive plate assemblies are arranged interlaced.

6. The transformer according to claim 1, wherein the transformer is applied to a power conversion circuit, and the power conversion circuit comprises a primary winding, a first secondary winding and a second secondary winding, wherein the winding assembly of the transformed forms the primary winding, the first secondary winding is a center tap and comprises a first end, a second end and a first center tap end, the second secondary winding is a center tap and comprises a third end, a fourth end and a second center tap end, wherein the conductive plate assembly comprises a first conductive plate assembly and a second conductive plate assembly, the first conductive plate assembly and the second conductive plate assembly form the first secondary winding and the second secondary winding, respectively, wherein both of the first conductive plate assembly and the second conductive plate assembly comprise a first conductive plate and a second conductive plate, respectively, the pin of each one of the first conductive plate comprises a first leg and a second leg, the pin of each one of the second conductive plates comprises a first leg and a second leg, wherein the first leg of the first conductive plate of the first conductive plate assembly is connected to the first center tap end, the second leg of the first conductive plate of the first conductive plate assembly is connected to the first end, the first leg of the first conductive plate of the second conductive plate assembly is connected to the first center tap end, the second leg of the first conductive plate of the second conductive plate assembly is connected to the second end, the first leg of the second conductive plate of the first conductive plate assembly is connected to the second center tap end, the second leg of the second conductive plate of the first conductive plate assembly is connected to the third end, the first leg of the second conductive plate of the second conductive plate assembly is connected to the second center tap end, and the second leg of the second conductive plate of the second conductive plate assembly is connected to the fourth end.

7. The transformer according to claim 6, wherein the first end of the first secondary winding, the second end of the first secondary winding, the third end of the second secondary winding and the fourth end of the second secondary winding are connected to the corresponding rectifiers, respectively.

8. The transformer according to claim 1, wherein the conductive plate assembly comprises at least one first conductive plate and at least one second conductive plate, the winding assembly is disposed between the first conductive plate and the second conductive plate, the extension direction of the pin of the first conductive plate is different from the extension direction of the pin of the second conductive plate, and the pin of the first conductive plate and the pin of the second conductive plate are connected to the corresponding circuit boards, respectively.

9. The transformer according to claim 8, wherein the transformer is applied to a power conversion circuit, and the power conversion circuit comprises a primary winding, a first secondary winding and a second secondary winding, wherein the winding assembly of the transformer forms the primary winding, the first secondary winding is a center tap and comprises a first end, a second end and a first center tap end, the second secondary winding is a center tap and comprises a third end, a fourth end and a second center tap end, wherein the conductive plate assembly comprises two first conductive plates and two second conductive plates, the two first conductive plates form the first secondary winding, the two second conductive plates form the second secondary winding, wherein the pin of each one of the first conductive plates comprises a first leg and a second leg, the pin of each one of the second conductive plates comprises a first leg and a second leg, wherein the first leg and the second leg of one of the two first conductive plates are connected to the first center tap end and the first end respectively, the first leg and the second leg of one of the two second conductive plates are connected to the first center tap end and the second end respectively, the first leg and the second leg of the other one of the two first conductive plates are connected to the second center tap end and the third end respectively, the first leg and the second leg of the other one of the second conductive plates are connected to the second center tap end and the fourth end respectively.

10. The transformer according to claim 1, wherein the magnetic core comprises the magnetic core pillar and four lateral pillars disposed around the magnetic core pillar, the magnetic core pillar is disposed at a center position of the magnetic core, and there is a gap between one of the lateral pillars and the other adjacent lateral pillar.

11. A transformer, comprising:
a magnetic core comprising a magnetic core pillar;
a bobbin disposed around the magnetic core pillar;
at least one winding assembly disposed around the bobbin to receive an input power; and
at least one conductive plate assembly disposed around the bobbin and electromagnetic coupled with the winding assembly via the magnetic core;
wherein the conductive plate assembly comprises at least two conductive plates, each of the conductive plates comprises a main body and a pin extending outwardly from the corresponding main body, wherein the extension directions of the pins of the at least two conductive plates extending outwardly from the corresponding main bodies are different from each other, the pins of the at least two conductive plates are connected to different circuit boards, and each of the circuit boards comprises at least one rectifier.

12. The transformer according to claim 11, wherein the bobbin comprises a channel for allowing the magnetic core pillar to insert therein, wherein the bobbin is disposed around the magnetic core pillar.

13. The transformer according to claim 11, wherein the main body of each one of the conductive plates has a hole, the holes of the at least two conductive plates of each one of the conductive plate assemblies are corresponding in position to each other so as to form an insertion part of the conductive plate assembly for allowing the bobbin to insert therein.

14. The transformer according to claim 11, wherein the at least one conductive plate assembly comprises at least one first conductive plate and at least one second conductive plate, the winding assembly is disposed between the first conductive plate and the second conductive plate, the extension direction of the pin of the first conductive plate is different from the extension direction of the pin of the second conductive plate, and the pin of the first conductive plate and the pin of the second conductive plate are connected to the corresponding circuit boards, respectively.
